(19) United States
(12) Patent Application Publication
(10) Pub. No.: US 2015/0369872 A1
(43) Pub. Date: Dec. 24, 2015

(54) Distance to Empty Prediction with Long Term Distance Compensation

(71) Applicant: Ford Global Technologies, LLC, Dearborn, MI (US)

(72) Inventors: Jason Meyer, Canton, MI (US); Sangeetha Sangameswaran, Canton, MI (US)

(21) Appl. No.: 14/309,070

(22) Filed: Jun. 19, 2014

(51) Int. Cl. G01R 31/36

(52) U.S. Cl. CPC G01R 31/3648; G01R 31/3606

(57) ABSTRACT

A vehicle is provided which may include an energy conversion device, an energy source to supply power to the energy conversion device, and at least one controller. The controller may be programmed to, in response to detecting one or more noise factors expected to affect propulsive energy consumption of the energy conversion device from vehicle start until the energy source is empty, output a distance to empty (DTE) based on a change in energy consumption rate due to the one or more noise factors and predicted to last at least until the energy source is empty. The controller may further include a DTE prediction architecture including a feed-forward energy consumption estimator, an energy consumption learning filter, and a DTE calculator. A method for estimating distance to empty for a vehicle is also provided which may output a DTE modified by a predicted change in energy consumption rate selected to include a compensation factor corresponding to and correcting for a noise factor.

### TECHNICAL FIELD

This disclosure relates to distance to empty prediction calculations for vehicles including an energy conversion device such as an electric machine or engine.

### BACKGROUND

Vehicles such as battery-electric vehicles (BEVs), plug-in hybrid-electric vehicles (PHEVs), mild hybrid-electric vehicles (MHEVs), or full hybrid-electric vehicles (FHEVs) contain a traction battery, such as a high voltage (HV) battery, to act as a propulsion source for the vehicle. The HV battery may include components and systems to assist in managing vehicle performance and operations. The HV battery may include one or more arrays of battery cells interconnected electrically between battery cell terminals and interconnector busbars. The HV battery and surrounding environment may include a thermal management system to assist in managing temperature of the HV battery components, systems, and individual battery cells. Vehicles with one or more HV batteries may include a battery management system that measures and/or estimates values descriptive of the HV battery, vehicle components, and/or battery cell present operating conditions. The battery management system may also output information relating to the measurements and estimates to an interface.

### SUMMARY

A method for estimating distance to empty for a vehicle includes, in response to detecting a noise factor expected to affect propulsive energy consumption from vehicle start to empty, outputting by a controller a DTE modified by a predicted change in energy consumption rate selected to include a compensation factor corresponding to and correcting for the noise factor. The DTE may be based on a predicted energy consumption rate and an amount of energy available in an energy source of the vehicle. The predicted energy consumption rate may be based on a historical nominal energy consumption rate and a current energy consumption rate. The noise factor may be a change in air density that occurred between an end of a last drive cycle and a subsequent vehicle start. The noise factor may be a change in position of a window or convertible top of the vehicle. The method may further include tracking a theoretical energy consumption rate by an energy consumption learning filter configured to remove effects of the noise factor to generate baseline operating conditions. The compensation factor may be a predicted DTE range adjustment corresponding to an estimated effect of the noise factor projected forward to empty. The noise factor may be detectable, predictable, and constant from vehicle start to empty.

A vehicle includes an energy conversion device, an energy source to supply power to the energy conversion device, and at least one controller. The controller is programmed to, in response to detecting one or more noise factors expected to affect propulsive energy consumption of the energy conversion device from vehicle start until the energy source is empty, output a distance to empty (DTE) based on a change in energy consumption rate due to the one or more noise factors and predicted to last at least until the energy source is empty. The controller may further include a DTE prediction architecture including a feed-forward energy consumption estimator, an energy consumption learning filter, and a DTE calculator. The DTE may be based on a predicted energy consumption rate and an amount of energy available in the energy source. The predicted energy consumption rate may be based on a historical nominal energy consumption rate and a current energy consumption rate. The one or more noise factors may include a change in air density that occurred between an end of a last drive cycle and a subsequent vehicle start. The one or more noise factors may include a change in position of a window or convertible top of the vehicle. The energy source may be a fuel tank or a traction battery.

A vehicle includes one or more sensors configured to monitor vehicle components and a traction battery pack and a controller. The controller is configured to receive input from the sensors, to detect one or more noise factors expected to affect propulsive energy consumption from vehicle start to empty based on the input, and to output a modified distance to empty (DTE) based on a change in energy consumption rate predicted to compensate for the one or more noise factors until empty. The controller may be further configured to update the change in energy consumption rate based on a change in the one or more noise factors. The controller may include a DTE prediction architecture including a feed-forward energy consumption estimator, an energy consumption learning filter, and a DTE calculator. The energy consumption rate may be based on a historical nominal energy consumption rate. The energy consumption rate may be further based on a current energy consumption rate.

### BRIEF DESCRIPTION OF THE DRAWINGS

FIG. 1 is a schematic illustration of a battery electric vehicle.

FIG. 2 is a block diagram illustrating an example of a vehicle.

FIG. 3 is a graph illustrating examples of distance to empty plots for the vehicle of FIG. 2.

FIG. 4 is a block diagram of an example of a distance to empty prediction architecture for the vehicle of FIG. 2.

FIG. 5 is a flow chart illustrating an example of an algorithm for operation of the distance to empty prediction architecture from FIG. 4.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

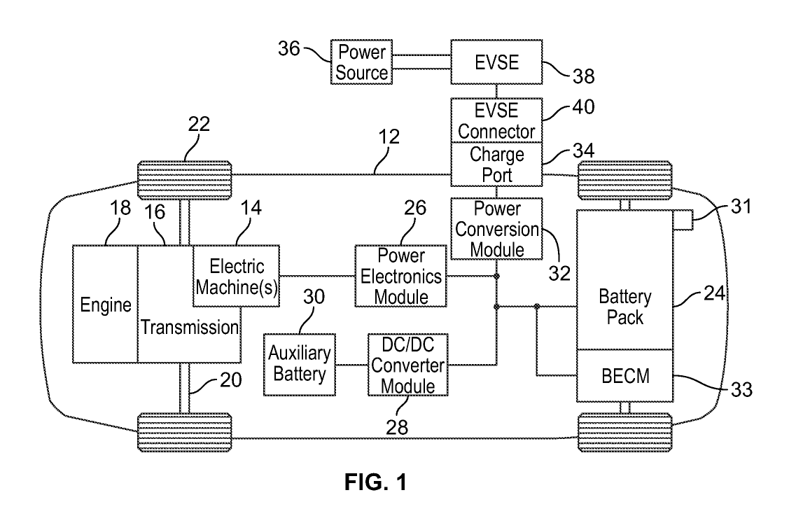

FIG. 1 depicts a schematic of a typical plug-in hybrid-electric vehicle (PHEV). A typical plug-in hybrid-electric vehicle 12 may comprise one or more electric machines 14 mechanically connected to a hybrid transmission 16. The electric machines 14 may be capable of operating as a motor or a generator. In addition, the hybrid transmission 16 is mechanically connected to an engine 18. The hybrid transmission 16 is also mechanically connected to a drive shaft 20 that is mechanically connected to the wheels 22. The electric machines 14 can provide propulsion and deceleration capability when the engine 18 is turned on or off. The electric machines 14 also act as generators and can provide fuel economy benefits by recovering energy that would normally be lost as heat in the friction braking system. The electric machines 14 may also provide reduced pollutant emissions since the hybrid-electric vehicle 12 may be operated in electric mode or hybrid mode under certain conditions to reduce overall fuel consumption of the vehicle 12.

A traction battery or battery pack 24 stores and provides energy that can be used by the electric machines 14. The traction battery 24 typically provides a high voltage DC output from one or more battery cell arrays, sometimes referred to as battery cell stacks, within the traction battery 24. The battery cell arrays may include one or more battery cells. The traction battery 24 is electrically connected to one or more power electronics modules 26 through one or more contactors (not shown). The one or more contactors isolate the traction battery 24 from other components when opened and connect the traction battery 24 to other components when closed. The power electronics module 26 is also electrically connected to the electric machines 14 and provides the ability to bi-directionally transfer electrical energy between the traction battery 24 and the electric machines 14. For example, a typical traction battery 24 may provide a DC voltage while the electric machines 14 may require a three-phase AC voltage to function. The power electronics module 26 may convert the DC voltage to a three-phase AC voltage as required by the electric machines 14. In a regenerative mode, the power electronics module 26 may convert the three-phase AC voltage from the electric machines 14 acting as generators to the DC voltage required by the traction battery 24. The description herein is equally applicable to a pure electric vehicle. For a pure electric vehicle, the hybrid transmission 16 may be a gear box connected to an electric machine 14 and the engine 18 may not be present.

In addition to providing energy for propulsion, the traction battery 24 may provide energy for other vehicle electrical systems. A typical system may include a DC/DC converter module 28 that converts the high voltage DC output of the traction battery 24 to a low voltage DC supply that is compatible with other vehicle loads. Other high-voltage loads, such as compressors and electric heaters, may be connected directly to the high-voltage without the use of a DC/DC converter module 28. In a typical vehicle, the low-voltage systems are electrically connected to an auxiliary battery 30 (e.g., 12V battery).

A battery electrical control module (BECM) 33 may be in communication with the traction battery 24. The BECM 33 may act as a controller for the traction battery 24 and may also include an electronic monitoring system that manages temperature and charge state of each of the battery cells. The traction battery 24 may have a temperature sensor 31 such as a thermistor or other temperature gauge. The temperature sensor 31 may be in communication with the BECM 33 to provide temperature data regarding the traction battery 24. The temperature sensor 31 may also be located on or near the battery cells within the traction battery 24. It is also contemplated that more than one temperature sensor 31 may be used to monitor temperature of the battery cells.

The vehicle 12 may be, for example, an electric vehicle such as a PHEV, a FHEV, a MHEV, or a BEV in which the traction battery 24 may be recharged by an external power source 36. The external power source 36 may be a connection to an electrical outlet. The external power source 36 may be electrically connected to electric vehicle supply equipment (EVSE) 38. The EVSE 38 may provide circuitry and controls to regulate and manage the transfer of electrical energy between the power source 36 and the vehicle 12. The external power source 36 may provide DC or AC electric power to the EVSE 38. The EVSE 38 may have a charge connector 40 for plugging into a charge port 34 of the vehicle 12. The charge port 34 may be any type of port configured to transfer power from the EVSE 38 to the vehicle 12. The charge port 34 may be electrically connected to a charger or on-board power conversion module 32. The power conversion module 32 may condition the power supplied from the EVSE 38 to provide the proper voltage and current levels to the traction battery 24. The power conversion module 32 may interface with the EVSE 38 to coordinate the delivery of power to the vehicle 12. The EVSE connector 40 may have pins that mate with corresponding recesses of the charge port 34.

The various components discussed may have one or more associated controllers to control and monitor the operation of the components. The controllers may communicate via a serial bus (e.g., Controller Area Network (CAN)) or via discrete conductors.

The battery cells, such as a prismatic cell, may include electrochemical cells that convert stored chemical energy to electrical energy. Prismatic cells may include a housing, a positive electrode (cathode) and a negative electrode (anode). An electrolyte may allow ions to move between the anode and cathode during discharge, and then return during recharge. Terminals may allow current to flow out of the cell for use by the vehicle. When positioned in an array with multiple battery cells, the terminals of each battery cell may be aligned with opposing terminals (positive and negative) adjacent to one another and a busbar may assist in facilitating a series connection between the multiple battery cells. The battery cells may also be arranged in parallel such that similar terminals (positive and positive or negative and negative) are adjacent to one another. For example, two battery cells may be arranged with positive terminals adjacent to one another, and the next two cells may be arranged with negative terminals adjacent to one another. In this example, the busbar may contact terminals of all four cells. The traction battery 24 may be heated and/or cooled using a liquid thermal management system, an air thermal management system, or other method as known in the art.

Accurately understanding energy consumption properties of various vehicle components is an integral part of estimating a distance to empty (DTE) range of vehicles having an energy conversion device, such as an engine or electric machine, and an energy source, such as a fuel tank or HV battery. In one example, DTE may be estimated based on a learned energy consumption rate and an amount of available energy. Multiple noise factors exist which may present challenges to estimating DTE under this approach. Some of these noise factors may change over an extended time scale while other noise factors may periodically change over a shorter time scale. Examples of noise factors may include vehicle mass/towing mass, vehicle condition which affects aerodynamic drag, tire characteristics, cabin temperature, climate control settings, coolant and oil temperature, ambient temperature, ambient pressure, precipitation, wind speed and direction, traffic, elevation, road grade, driving style, and braking habits.

Examples of noise factors which tend to change over an extended time scale include ambient temperature changes and tire deflation. Examples of noise factors which tend to periodically change over a shorter time scale include oil warm-up and cabin heating/cooling. Additionally, certain noise factors, such as vehicle mass/towing mass, elevation and posted speed limits, may change over an extended time scale or a shorter time scale. Energy consumption over a fixed time scale may be observed to learn the energy consumption efficiency. However, the above described approach may not distinguish between short-term fluctuations in energy consumption (which should be compensated but not projected forward) and longer term shifts in energy consumption (which should be projected forward to empty). If a time scale is too long, then an average effect of noise factors which tend to change over shorter time scales may be well captured, but the estimation may respond very slowly to noise factors which tend to change over extended time scales. Conversely, a short time scale may allow the estimation to adeptly capture the effects of noise factors which tend to vary over extended time scales, but the estimation may be susceptible to an over correction for noise factors which tend to change over shorter time scales. In either case, a common result may be an inaccurate estimation for DTE.

For example, an energy consumption rate for a vehicle during the first few minutes of a key on cycle or vehicle start may be greater, in certain circumstances as high as double, than the normal energy consumption rate of the vehicle. The above approach may over-predict DTE at a key on stage and then may over compensate for the observed high energy consumption rate which may result in underestimating DTE. Multiple short trips may cause the estimated DTE to oscillate such that a driver does not have clarity on the vehicle range. Extended time periods between vehicle operation cycles may cause the estimated DTE to undercompensate or overcompensate for certain noise factors. These types of inaccuracies may lead to driver dissatisfaction and particularly to drivers of BEVs and PHEVs.

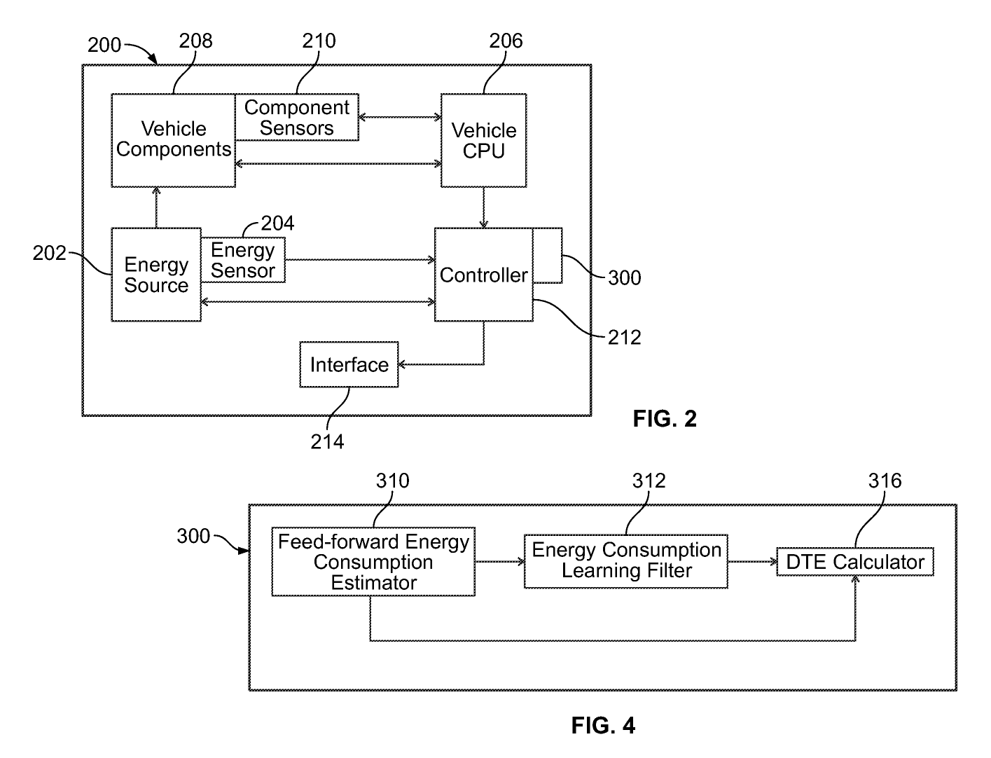

FIG. 2 shows a vehicle 200 which may include an energy source 202. The vehicle 200 may be, for example, a BEV, PHEV, or a vehicle with a combustion engine. An energy sensor 204 may be in communication with the energy source 202, such as an HV battery pack or a fuel tank, to measure power levels of battery cells within the HV battery pack or a fuel level of the fuel tank. The energy sensor 204 for an HV battery pack may include a current sensor, a voltage sensor, and an accompanying battery control unit. The energy sensor 204 may be located in a suitable position including within, adjacent to, or proximate to the energy source 202. A vehicle computer processing unit (“CPU”) 206 may be in communication with a plurality of vehicle components 208 and a plurality of component sensors 210 such that the CPU 206 may receive information regarding the vehicle components 208 and also direct operation thereof. Non-limiting examples of vehicle components 208 may include an engine, a transmission, a differential, an after treatment system, a lubrication system, electric machines, tires, a cabin climate control system, a battery pack thermal management system, an engine thermal management system, an electric machine thermal management system, windows, sunroofs, and retractable convertible tops. The component sensors 210 may include sensors appropriate to measure conditions of the corresponding vehicle component 208. For example, the energy sensor 204 may be a battery state of charge estimator. As another example in which the vehicle 200 includes an engine and fuel tank, the energy sensor 204 may be a fuel level sensor. A controller 212 may be in communication with the vehicle CPU 206, the energy sensor 204, and the energy source 202 to receive information relating to the vehicle components 208 and the energy source 202. The controller 212 may also be in communication with an interface 214 located in a cabin of the vehicle 200 to display and/or communicate information relating to the vehicle components 208 and the energy source 202. The component sensors 210 may also include an ambient air temperature sensor and ambient air pressure sensor which together may measure ambient air density.

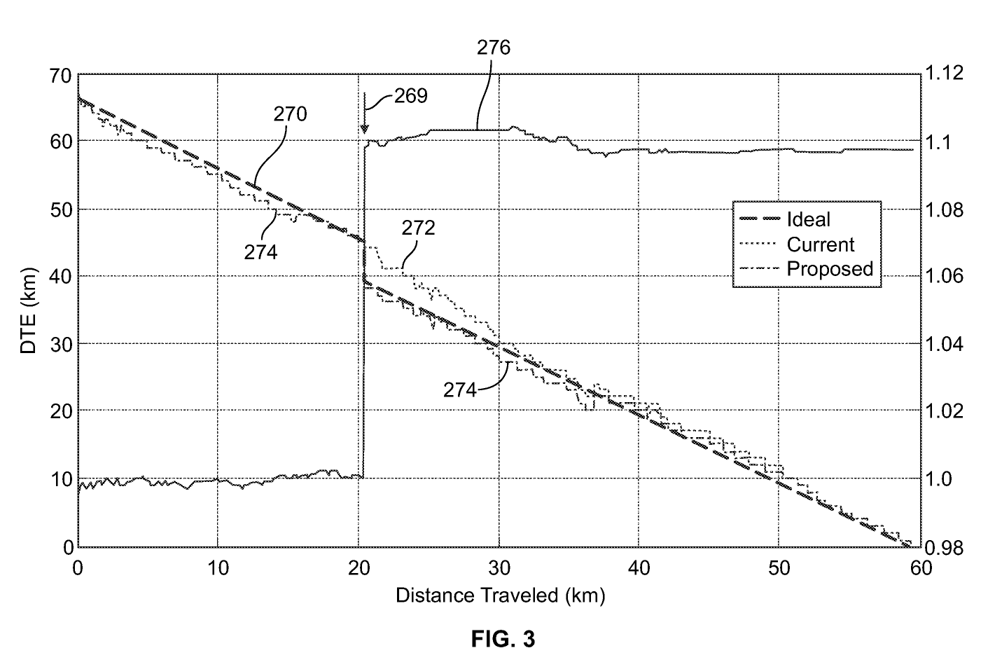

FIG. 3 is a graph showing examples of three DTE calculation plots and a feed forward compensation factor. In an example scenario, the vehicle 200 may be driven for 20 km and then keyed off. The vehicle 200 may then sit for a time period, such as a month. At the next key on cycle or vehicle start represented by arrow 269, an ambient temperature is lower than when the vehicle 200 was keyed off. The vehicle 200 then reaches empty after 40 km from key on or vehicle start.

An illustrative DTE plot 270 may be a plot representing a theoretical DTE defined by a decrement rate of 1 km per 1 km of distance traveled during a drive cycle of the vehicle 200. The illustrative DTE plot 270 may be used as a baseline to compare examples of outputs of DTE calculations. A DTE without feed forward compensation plot 272 is shown which may represent DTE calculations taken without utilizing a predicted change in energy consumption rate which may compensate and correct for one or more long term noise factors. For example, the DTE without feed forward compensation plot 272 may be based on a learned energy consumption rate of the vehicle 200, however the learned energy consumption rate used in the DTE calculations may not accurately account for the different types of noise factors including long term noise factors. Referring to x-axis values 20 km to 50 km, the DTE without feed forward compensation plot 272 is shown to decrement a rate higher than 1 km per 1 km driven due to the change in air density (from approximately 20 km to 50 km) until the new energy consumption rate of the vehicle 200 is learned by the system. This results in inaccurate DTE information output to the interface 214 due to inaccurate compensation for long term noise factors.

A feed forward compensation factor plot 276 shows an input which may assist in compensating for long term noise factors, such as a change in ambient temperature as described above. For example, a DTE with feed forward compensation plot 274 may represent an application of a feed-forward compensation factor for detected long term noise factors which (i) may be detected using component sensors 210, (ii) have an effect which may be predicted, and (iii) may be assumed to be constant or existing until empty. Examples of noise factors which may meet these criteria include ambient air density, window status, sunroof status, convertible top status, vehicle mass/towing mass, and resting tire pressure. Compensating for these noise factors may provide a more accurate energy consumption efficiency estimate and thus positively impact DTE calculations. The feed forward compensation factor plot 276 may represent DTE calculations which may compensate for a change in a state, value, or condition of a detected long term noise factor. In this example, normalized ambient air density is predicted to be at substantially 1.1 for the duration of the drive cycle following the vehicle start at arrow 269. As shown by the DTE with feed forward compensation plot 274, utilizing calculations which compensate for one or more long term noise factors, in this example air density, provides a modified DTE output much closer to the illustrative DTE plot 270.

FIG. 4 shows one example of a DTE prediction architecture, referenced generally by numeral 300, which may include a feed-forward energy consumption estimator 310, an energy consumption learning filter 312, and a DTE calculator 316. The DTE prediction architecture 300 may be in communication with the controller 212. The feed-forward energy consumption estimator 310 may include transfer function models for known and detectable long term noise factors. The transfer function models may each consider signals from the component sensors 210 relating to the according vehicle components 208 as inputs. Based on the inputs, the feed-forward energy consumption estimator 310 may output a predicted change in energy consumption rate (e.g. Whr/km or gallons/100 km) which may be an expected energy consumption effect of the respective noise factors. In the example of ambient air density as a long term noise factor, an amplitude of an aerodynamic draft force is proportional to the ambient air density. A transfer function for the air density may be the product of a learned energy consumption rate and compensation factor, sometimes referred to as a gain factor, which is scheduled on air density. When air density is higher than a nominal value, the gain factor may be positive as shown in FIG. 3. When the air density is less than the nominal value, the gain factor may be negative.

The energy consumption learning filter 312 may receive inputs different than that of previous energy consumption learning filters. For example, the energy consumption learning filter 312 may learn a long term energy consumption rate of the vehicle by filtering an input energy consumption rate. Rather than directly inputting only a current energy consumption rate, the predicted change in energy consumption rate from the feed-forward energy consumption estimator 310 is subtracted from a current energy consumption rate (e.g. Whr/km or gallons/100 km) prior to being input into the energy consumption learning filter 312. Thus, the energy consumption learning filter 312 tracks a theoretical energy consumption rate that would be achieved if all of the detectable long term noise factors were removed, e.g. a nominal air density, windows closed, sunroof closed, convertible top closed, a nominal vehicle mass/towing mass, and a nominal resting tire pressure. The result may be referred to as a nominal energy consumption rate (Whr/km) which may be input into the DTE calculator 316.

For an electrified vehicle, such as a BEV or PHEV, the DTE calculator 316 may calculate an amount of energy available (Whr) in the battery pack based on one or more signals received from the energy sensor 204. For a conventional vehicle, the DTE calculator may calculate an amount of energy available in terms of fuel volume (gallons) in the fuel tank based on a fuel level sensor. The DTE calculator 316 may also calculate a predicted energy consumption rate (Whr/km or gallons/100 km) based on the predicted change in energy consumption rate and the nominal energy consumption rate received from the energy consumption learning filter 312. The DTE calculator 316 may then calculate a DTE (km) based on the energy available and the predicted energy consumption rate due to the detected one or more long term noise factors.

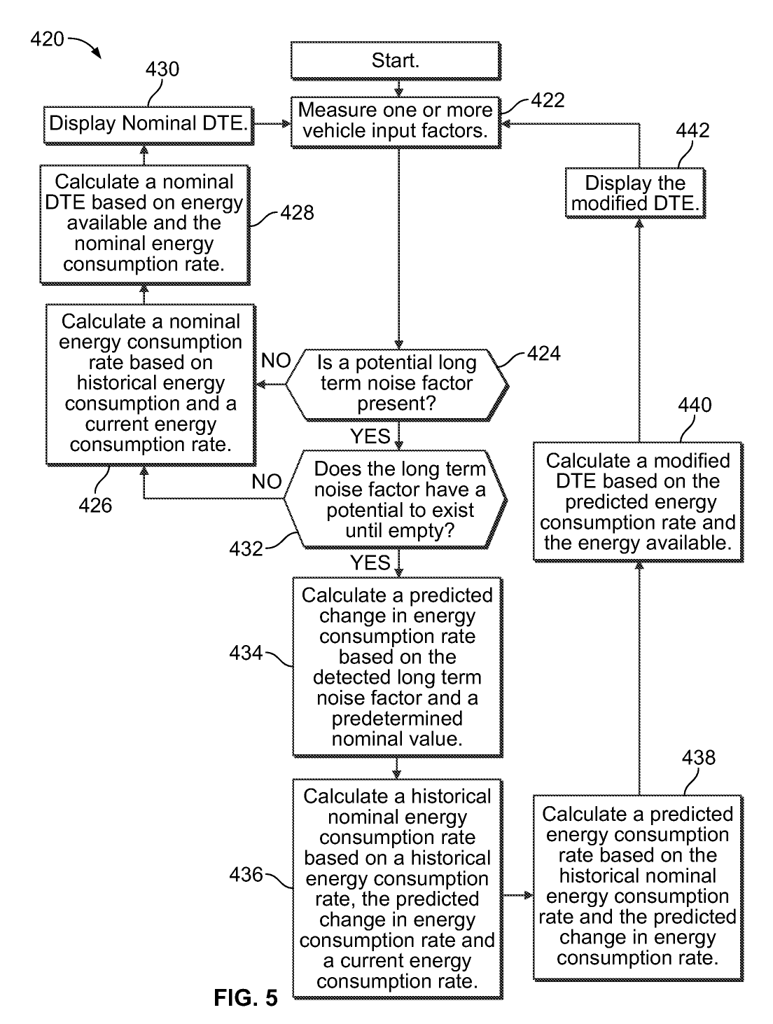

FIG. 5 shows an example of an algorithm for calculating a modified DTE for a vehicle which may compensate for long term noise factors. The algorithm is generally indicated by reference numeral 420. In operation 422, one or more sensors may measure one or more input factors and input the measurements into a feed-forward energy consumption estimator. As described above, various factors may be measured such as air density, window status, sunroof status, convertible top status, vehicle mass/towing mass, and resting tire pressure. Under certain conditions, estimated values may be used as input factors such as tire temperature or combustion efficiency. If a controller does not detect a long term noise factor in operation 424, in operation 426 an energy consumption learning filter may calculate a nominal energy consumption rate based on historical energy consumption of the vehicle and a current energy consumption rate based on input factors. In operation 428, a DTE calculator may calculate a nominal DTE based on energy available and the energy consumption rate calculated in operation 426. In operation 430, the controller may direct output of the nominal DTE on an interface and prior to measuring the one or more vehicle input factors in operation 422 of the algorithm.

If the controller detects a potential long term noise factor in operation 424, the controller may determine whether the long term noise factor has a potential to exist until the vehicle runs to empty in operation 432. For example, air density at vehicle start may be identified as a long term noise factor since the air density typically remains at a constant during a drive cycle, but may be a different value in comparison to the previous drive cycle. As another example, an open window or convertible top may be identified as long term noise factors under certain conditions. The sensors in communication with the window and/or convertible top may also detect a status change, such as a status change from a closed position to open, and trigger a new DTE calculation in response to the status change. In operation 434, the feed-forward energy consumption estimator may calculate a predicted change in energy consumption rate (e.g. Whr/km or gallons/100 km) for the vehicle based on the long term noise factor detected and measured. Under certain conditions, the predicted change in energy consumption rate may also be based on one or more predetermined nominal values for the long term noise factors. For example, the nominal air density might correspond to the density at 20 degrees Celsius at sea level, the nominal resting tire pressure might correspond to the recommended tire inflation pressure and the nominal vehicle mass might correspond to the certified vehicle curb weight.

In operation 436, the energy consumption learning filter may calculate a historical nominal energy consumption rate based on a historical energy consumption rate, the predicted change in energy consumption rate, and a current energy consumption rate (e.g. Whr/km or gallons/100 km). The historical energy consumption rate may include stored information relating to previous drive cycles of the vehicle. The current energy consumption rate may be based on an energy output rate of an energy source relative to a distance. For example, the current energy consumption rate may be based on information received from one or more sensors in communication with vehicle components.

In operation 438, the DTE calculator may calculate a predicted energy consumption rate (e.g. Whr/km or gallons/100 km) based on the historical nominal energy consumption rate and the predicted change in energy consumption rate. As described above, under certain conditions the one or more sensors may update the input factor measurements based on status and/or condition changes of the vehicle components. In operation 440, the DTE calculator may calculate a DTE (km) based on the predicted energy consumption rate and an amount of energy available (e.g. Whr or gallons). For example a sensor, such as a fuel level sensor or an energy level sensor, may measure available energy in an energy source of the vehicle. In operation 442, the controller may direct output of the modified DTE on an interface. As described above, this modified DTE may compensate and correct for the one or more long term noise factors. As shown the FIG. 5, the algorithm indicated by reference numeral 420 may cycle throughout vehicle drive cycles.

While various embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to marketability, appearance, consistency, robustness, customer acceptability, reliability, accuracy, etc. As such, embodiments described as less desirable than other embodiments or prior art implementations with respect to one or more characteristics are not outside the scope of the disclosure and can be desirable for particular applications.

What is claimed is:

1. A method for estimating distance to empty (DTE) for a vehicle comprising:
in response to detecting a noise factor expected to affect propulsive energy consumption from vehicle start to empty, outputting by a controller a DTE modified by a predicted change in energy consumption rate selected to include a compensation factor corresponding to and correcting for the noise factor.

2. The method of claim 1, wherein the DTE is based on a predicted energy consumption rate and an amount of energy available in an energy source of the vehicle.

3. The method of claim 2, wherein the predicted energy consumption rate is based on a historical nominal energy consumption rate and a current energy consumption rate.

4. The method of claim 3, wherein the noise factor is a change in air density that occurred between an end of a last drive cycle and a subsequent vehicle start.

5. The method of claim 3, wherein the noise factor is a change in position of a window or convertible top of the vehicle.

6. The method of claim 1 further comprising tracking a theoretical energy consumption rate by an energy consumption learning filter configured to remove effects of the noise factor to generate baseline operating conditions.

7. The method of claim 1, wherein the compensation factor is a predicted DTE range adjustment corresponding to an estimated effect of the noise factor projected forward to empty.

8. The method of claim 1, wherein the noise factor is detectable, predictable, and constant from vehicle start to empty.

9. A vehicle comprising:
an energy conversion device;
an energy source to supply power to the energy conversion device; and
at least one controller programmed to, in response to detecting one or more noise factors expected to affect propulsive energy consumption of the energy conversion device from vehicle start until the energy source is empty, output a distance to empty (DTE) based on a change in energy consumption rate due to the one or more noise factors and predicted to last at least until the energy source is empty.

10. The vehicle of claim 9, wherein the controller further comprises a DTE prediction architecture including a feed-forward energy consumption estimator, an energy consumption learning filter, and a DTE calculator.

11. The vehicle of claim 9, wherein the DTE is based on a predicted energy consumption rate and an amount of energy available in the energy source.

12. The vehicle of claim 11, wherein the predicted energy consumption rate is based on a historical nominal energy consumption rate and a current energy consumption rate.

13. The vehicle of claim 9, wherein the one or more noise factors include a change in air density that occurred between an end of a last drive cycle and a subsequent vehicle start.

14. The vehicle of claim 9, wherein the one or more noise factors include a change in position of a window or convertible top of the vehicle.

15. The vehicle of claim 9, wherein the energy source is a fuel tank or a traction battery.

16. A vehicle comprising:
one or more sensors configured to monitor vehicle components and a traction battery pack; and
a controller configured to receive input from the sensors, to detect one or more noise factors expected to affect propulsive energy consumption from vehicle start to empty based on the input, and to output a modified distance to empty (DTE) based on a change in energy consumption rate predicted to compensate for the one or more noise factors until empty.

17. The vehicle of claim 16, wherein the controller is further configured to update the change in energy consumption rate based on a change in the one or more noise factors.

18. The vehicle of claim 16, wherein the controller comprises a DTE prediction architecture including a feed-forward energy consumption estimator, an energy consumption learning filter, and a DTE calculator.

19. The vehicle of claim 16, wherein the energy consumption rate is based on a historical nominal energy consumption rate.

20. The vehicle of claim 19, wherein the energy consumption rate is further based on a current energy consumption rate.
